(19) United States
(12) Patent Application Publication
(10) Pub. No.: US 2020/0089356 A1
(43) Pub. Date: Mar. 19, 2020

(54) TOUCH DISPLAY SUBSTRATE, METHOD OF MANUFACTURING THE SAME, AND TOUCH DISPLAY APPARATUS

(71) Applicants: Chengdu BOE Optoelectronics Technology Co., Ltd., Chengdu (CN); BOE Technology Group Co., Ltd., Beijing (CN)

(72) Inventors: Mingchun Qi, Beijing (CN); Yan Cui, Beijing (CN); Yu Wang, Beijing (CN); Chunhui Zhu, Beijing (CN); Shan Mou, Beijing (CN)

(21) Appl. No.: 16/393,156

(22) Filed: Apr. 24, 2019

(30) Foreign Application Priority Data
Sep. 18, 2018 (CN) 201811089863.5

(51) Int. Cl. G06F 3/041; G02F 1/1333; H01L 27/32; G02F 1/1368

(52) U.S. Cl. CPC G06F 3/0412; G02F 1/13338; H01L 27/323; G06F 2203/04107; G06F 2203/04103; G06F 2203/04102; G02F 1/1368

(57) ABSTRACT

A touch display substrate, a method of manufacturing the same, and a touch display apparatus are provided. In one embodiment, A touch display substrate includes: a base substrate; a plurality of color photoresists on the base substrate; a black matrix configured to separate the plurality of color photoresists; and a touch layer including a plurality of first touch electrodes arranged in a first direction and a plurality of second touch electrodes arranged in a second direction, the second direction being different from the first direction; wherein the first touch electrodes intersect with the second touch electrodes, and the first touch electrodes and the second touch electrodes are insulated from each other at intersections of the first touch electrodes and the second touch electrodes by the black matrix.

### CROSS-REFERENCE TO RELATED APPLICATION

This application claims the benefit of Chinese Patent Application No. 201811089863.5, filed with the State Intellectual Property Office of China on Sep. 18, 2018, the whole disclosure of which is incorporated herein by reference.

### TECHNICAL FIELD

The present disclosure relates to a field of touch display technology, and in particular, to a touch display substrate, a method of manufacturing the same, and a touch display apparatus.

### BACKGROUND

At present, Touch Screen Panel (TSP in short) is a new multimedia human-computer interaction device, which is mainly used in many fields, such as public information inquiry, electronic games, karaoke, a la carte, or multimedia teaching, etc.

### SUMMARY

According to an aspect of embodiments of the present disclosure, there is provided a touch display substrate including:

a base substrate ;

a plurality of color photoresists on the base substrate;

a black matrix configured to separate the plurality of color photoresists; and

a touch layer including a plurality of first touch electrodes arranged in a first direction and a plurality of second touch electrodes arranged in a second direction, the second direction being different from the first direction;

wherein the first touch electrodes intersect with the second touch electrodes, and the first touch electrodes and the second touch electrodes are insulated from each other at intersections of the first touch electrodes and the second touch electrodes by the black matrix.

In some exemplary embodiments, the first touch electrodes and the second touch electrodes are in a same layer, each of the first touch electrodes includes a plurality of directly connected first touch sub-electrodes, and each of the second touch electrodes includes a plurality of separately arranged second touch sub-electrodes; and

the touch layer further includes: bridges provided respectively at the intersections of the first touch electrodes and the second touch electrodes and configured to connect adjacent ones of the second touch sub-electrodes.

In some embodiments, adjacent ones of the bridges are spaced apart by one or more of the color photoresists.

In some embodiments, the bridge is made of conductive material, and the black matrix is made of non-conductive material.

In some further exemplary embodiments, the first touch electrodes and the second touch electrodes are in different layers, and, in a direction perpendicular to the base substrate, the first touch electrodes, the black matrix, and the second touch electrodes are arranged on the base substrate successively.

In some embodiments, both the first touch electrodes and the second touch electrodes are strip-shaped electrodes, and the black matrix is made of non-conductive material.

In some embodiments, an orthographic projection of the black matrix on the base substrate at least covers an overlapping region of an orthographic projection of the first touch electrode on the base substrate and an orthographic projection of the second touch electrode on the base substrate.

In some embodiments, ones of the first touch electrodes and the second touch electrodes are driving electrodes and the others are touch sensor electrodes.

In some embodiments, the base substrate is a flexible base substrate.

In some embodiments, the touch display substrate further includes: a planarization layer provided at a side of the touch layer, the color photoresists and the black matrix away from the base substrate.

According to another aspect of embodiments of the present disclosure, there is provided a touch display apparatus including the touch display substrate of any one of the above embodiments.

In some exemplary embodiments, the touch display substrate further includes: a display layer and a packaging layer provided at a side of the touch layer, the color photoresists and the black matrix close to the base substrate, the display layer being between the base substrate and the packaging layer; and

wherein the display layer includes a plurality of sub-pixels, each of which includes a first electrode, a light-emitting function layer and a second electrode.

In some embodiments, the touch display apparatus further includes: an array substrate, and a liquid crystal layer between the array substrate and the touch display substrate.

According to yet another aspect of embodiments of the present disclosure, there is provided a method of manufacturing the touch display substrate of any one of the above embodiments, and the method includes:

forming, on the base substrate, the plurality of color photoresists and the black matrix configured to separate the plurality of color photoresists; and

forming the touch layer including the plurality of first touch electrodes arranged in the first direction and the plurality of second touch electrodes arranged in the second direction, wherein the first touch electrodes intersect with the second touch electrodes, and the first touch electrodes and the second touch electrodes are insulated from each other at the intersections of the first touch electrodes and the second touch electrodes by the black matrix.

In some exemplary embodiments, the method of manufacturing the touch display substrate specifically includes: forming, on the base substrate, the plurality of first touch electrodes arranged in the first direction and the plurality of second touch electrodes arranged in the second direction, wherein the first touch electrodes intersect with the second touch electrodes, and each of the first touch electrodes includes a plurality of directly connected first touch sub-electrodes, and each of the second touch electrodes includes a plurality of separately arranged second touch sub-electrodes;

forming the plurality of color photoresists and the black matrix configured to separate the plurality of color photoresists, the black matrix at least covering a portion of the first touch electrode at the intersection of the first touch electrode and the second touch electrode; and

forming bridges respectively at the intersections of the first touch electrodes and the second touch electrodes, the bridges being configured to connect adjacent ones of the second touch sub-electrodes.

In some embodiments, the step of forming the bridges respectively at the intersections of the first touch electrodes and the second touch electrodes further includes: forming a conductive film, and patterning the conductive film to form the bridges.

In some further exemplary embodiments, the method of manufacturing the touch display substrate specifically includes:

forming bridges on the base substrate;

forming the plurality of color photoresists and the black matrix configured to separate the plurality of color photoresists, the black matrix being at least located above the bridges;

forming the plurality of first touch electrodes arranged in the first direction and the plurality of second touch electrodes arranged in the second direction, wherein the first touch electrodes intersect with the second touch electrodes, and each of the first touch electrodes includes a plurality of directly connected first touch sub-electrodes, and each of the second touch electrodes includes a plurality of separately arranged second touch sub-electrodes, adjacent ones of the second touch sub-electrodes are connected by the bridges, and the bridges and the first touch electrodes are insulated from each other by the black matrix.

In some embodiments, the step of forming the bridges further includes: forming a conductive film, and patterning the conductive film to form the bridges.

In some still further exemplary embodiments, the method of manufacturing the touch display substrate specifically includes:

forming, on the base substrate, the plurality of first touch electrodes arranged in the first direction;

forming the plurality of color photoresists and the black matrix configured to separate the plurality of color photoresists; and

forming the plurality of second touch electrodes arranged in the second direction, wherein the first touch electrodes intersect with the second touch electrodes, and the first touch electrodes and the second touch electrodes are insulated from each other at the intersections of the first touch electrodes and the second touch electrodes by the black matrix.

In some embodiments, the black matrix is made of non-conductive material, an orthographic projection of the black matrix on the base substrate at least covers an overlapping region of an orthographic projection of the first touch electrode on the base substrate and an orthographic projection of the second touch electrode on the base substrate, and ones of the first touch electrodes and the second touch electrodes are driving electrodes and the others are touch sensor electrodes.

### BRIEF DESCRIPTION OF THE DRAWINGS

In order to describe embodiments of the present disclosure or technical solutions in the related art more clearly, accompanying drawings required for describing the embodiments or the related art will be simply explained as below. Apparently, the accompanying drawings for the following description are only some embodiments of the present disclosure. Those skilled in the art also could derive other accompanying drawings from these accompanying drawings without making a creative work.

FIG. 1 is a schematic view showing a structure of a touch display apparatus in a related art;

FIG. 2(a) is a schematic view showing a structure of a touch display substrate according to an embodiment of the present disclosure;

FIG. 2(b) is a schematic view showing a structure of a touch display substrate according to another embodiment of the present disclosure;

FIG. 2(c) is a schematic view showing a structure of a touch display substrate according to yet another embodiment of the present disclosure;

FIG. 3 is a schematic view showing a structure of a touch display substrate according to still another embodiment of the present disclosure;

FIG. 4 is a schematic view showing a structure of a touch display substrate according to yet still another embodiment of the present disclosure;

FIG. 5 is a schematic view showing a structure of a touch display substrate according to a further embodiment of the present disclosure;

FIG. 6 is a schematic view showing a structure of a touch display substrate according to a still further embodiment of the present disclosure;

FIG. 7 is a schematic view showing a structure of an OLED (Organic Light-Emitting Diode) touch display apparatus or a QLED (Quantum dot Light-Emitting Display) touch display apparatus according to an embodiment of the present disclosure;

FIG. 8 is a schematic view showing a structure of an OLED touch display apparatus or a QLED touch display apparatus according to another embodiment of the present disclosure;

FIG. 9 is a schematic view showing a structure of a liquid crystal touch display apparatus according to an embodiment of the present disclosure;

FIG. 10 is a schematic view showing a structure of a touch display substrate according to a yet further embodiment of the present disclosure;

FIG. 11 is a schematic view showing a structure of a first touch electrode and a second touch electrode according to an embodiment of the present disclosure;

FIG. 12 is a schematic view showing a structure of formation of a black matrix on a first touch electrode and a second touch electrode according to an embodiment of the present disclosure;

FIG. 13 is a fundamental flow diagram of a method of manufacturing a touch display substrate according to an embodiment of the present disclosure;

FIG. 14 is an exemplary flow diagram of a method of manufacturing a touch display substrate according to an embodiment of the present disclosure;

FIG. 15 is an exemplary flow diagram of a method of manufacturing a touch display substrate according to another embodiment of the present disclosure; and

FIG. 16 is an exemplary flow diagram of a method of manufacturing a touch display substrate according to still another embodiment of the present disclosure.

### DETAILED DESCRIPTION

A clear and complete description of technical solutions in embodiments of the present disclosure and in related art will be made as below in conjunction with the accompanying drawings in the embodiments of the present disclosure and in related art. Apparently, the described embodiments are some of the embodiments of the present disclosure rather than all of the embodiments of the present disclosure. All other embodiments derived by those skilled in the art based on the embodiments of the present disclosure without making a creative work shall fall within the protection scope of the present disclosure.

Referring to FIG. 1, a conventional touch display apparatus (in FIG. 1 the conventional touch display apparatus is illustrated by taking an Organic Electro-luminescent Display (OLED for short) as an example) usually adopts a simple superimposition of a display layer 10, a touch layer 20 and a color filter 30. Although the color effect and the human-computer interaction effect are achieved, when the three layers are superimposed, a first insulating layer 40 needs to be provided between the touch layer 20 and the color filter 30 and a second insulating layer 50 needs to be provided at intersections of first touch electrodes 201 and second touch electrodes 202 of the touch layer 20. The total thickness of the first insulating layer 40 and the second insulating layer 50 is about 6000 angstroms. Therefore, provision of the two insulating layers causes the thickness of the touch display apparatus to be large, and the large thickness of the touch display apparatus may cause some performances of the touch display apparatus to be unsatisfactory. For example, for the flexible touch display apparatus, the display apparatus is not easily bent, and the problem of screen breakage is prone to occur.

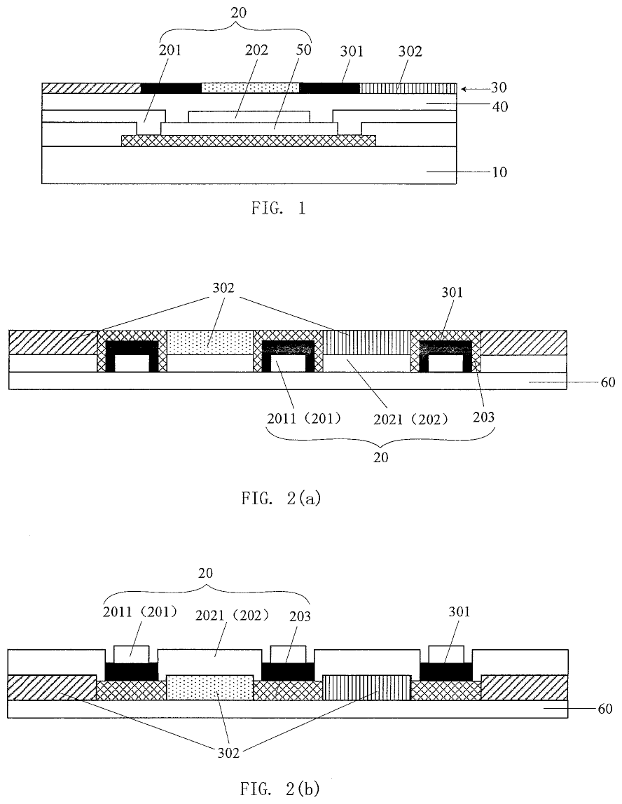

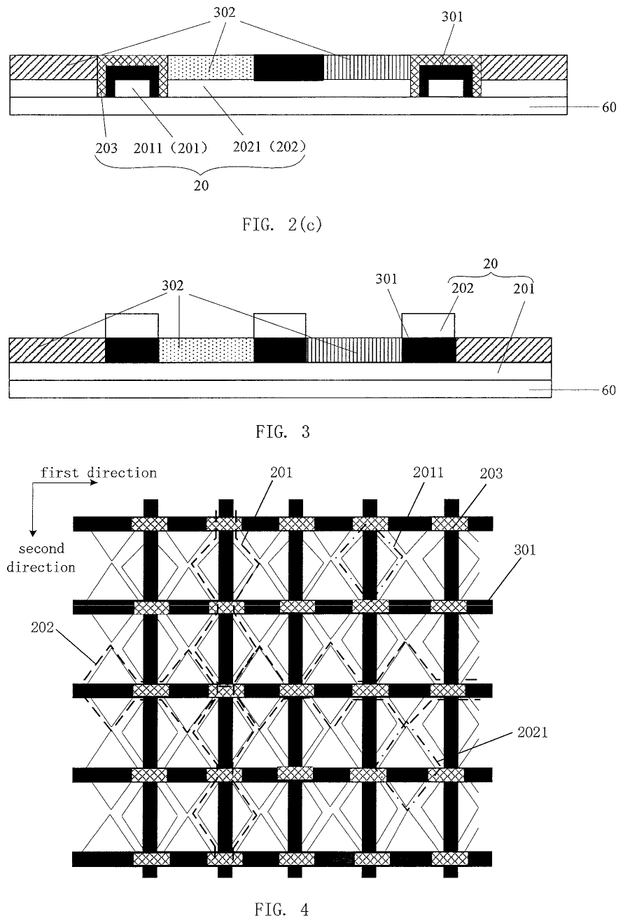

According to embodiments of the present disclosure, referring to FIG. 2(a), FIG. 2(b) and FIG. 3, there is provided a touch display substrate including a base substrate 60; a plurality of color photoresists 302 on the base substrate 60; a black matrix (BM for short) pattern 301 configured to separate the plurality of color photoresists 302; and a touch layer 20 including a plurality of first touch electrodes 201 arranged in a first direction and a plurality of second touch electrodes 202 arranged in a second direction, the second direction being different from the first direction. The first touch electrodes 201 intersect with the second touch electrodes 202, and the first touch electrodes 201 and the second touch electrodes 202 are insulated from each other at intersections of the first touch electrodes 201 and the second touch electrodes 202 by the black matrix 301.

It should be explained that, firstly, in the embodiments of the present disclosure, the specific material of the black matrix 301 is not limited as long as it is a light-shielding and insulating material. For example, the material of the black matrix 301 may be a black resin or a black ink or the like.

Secondly, in the embodiments of the present disclosure, the color photoresists 302, for example, may be a red photoresist pattern (R), a green photoresist pattern (G) and a blue photoresist pattern (B), or may be a yellow photoresist pattern, a magenta photoresist pattern and a cyan photoresist pattern. By way of example, photoresist patterns 302 in different shadings in the figures represent photoresist patterns of different colors, respectively. In addition, in the embodiments of the present disclosure, there is no limitation on the layout manner among the photoresist patterns 302 of different colors, as long as it meets the display requirements.

Thirdly, in the embodiments of the present disclosure, there is no limitation on specific types of the first touch electrode 201 and the second touch electrode 202. For example, the first touch electrode 201 is a driving electrode (Tx) and the second touch electrode 202 is a touch sensor electrode (Rx); or else, the first touch electrode 201 is a touch sensor electrode (Rx) and the second touch electrode 202 is a driving electrode (Tx).

On this basis, specific materials of the first touch electrode 201 and the second touch electrode 202 are not limited as long as they are transparent conductive materials. For example, the materials of the first touch electrode 201 and the second touch electrode 202 are ITO (Indium Tin Oxide), IZO (Indium Zinc Oxide), Ti/Al/Ti laminate, or the like.

In addition, the first touch electrode 201 and the second touch electrode 202 intersect with each other. For an example, the first touch electrode 201 and the second touch electrode 202 may be perpendicular to each other, for another example, an angle between the first touch electrode 201 and the second touch electrode 202 may be an acute angle. In the figures of the accompanying drawings showing the embodiments of the present disclosure, the first touch electrode 201 and the second touch electrode 202 are perpendicular to each other as an example.

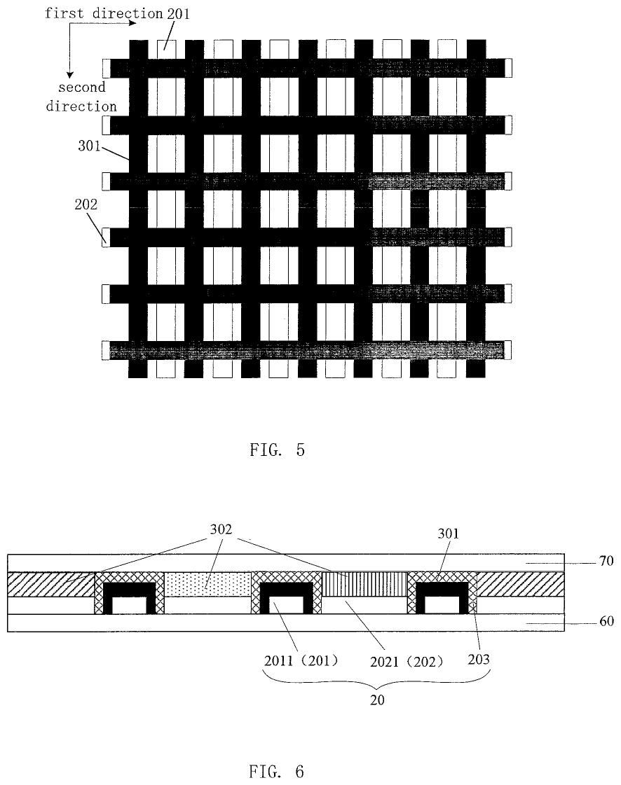

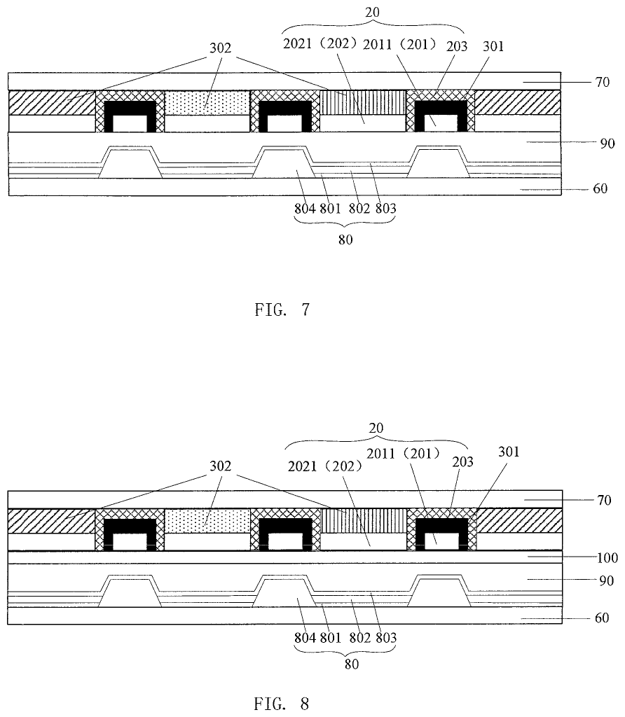

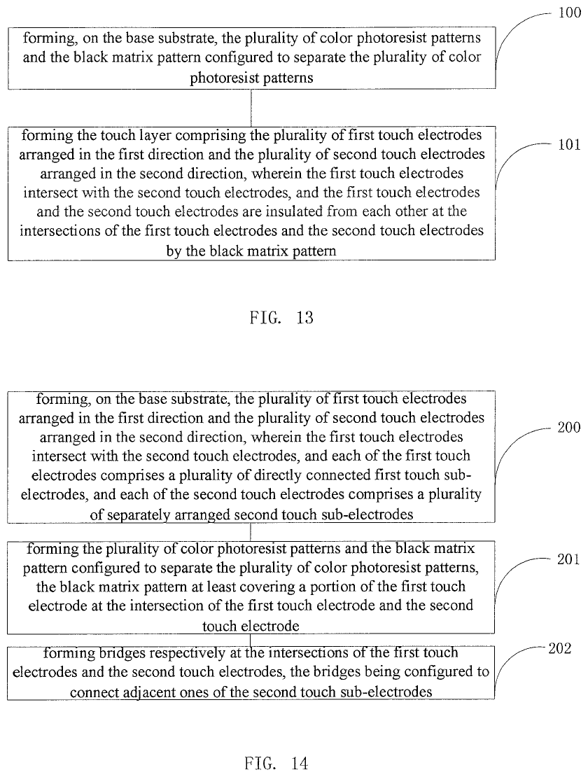

Fourthly, in the embodiments of the present disclosure, there is no limitation on specific structure of the touch layer 20, but two exemplary specific structures of the touch layer 20 are described in details hereinafter. It should be noted that, in FIG. 4 which is to be described hereinafter and which relates to an exemplary specific structure of the touch layer 20 of the touch display substrate, thick black lines represent the black matrix 301, rectangles with grid shadings in the thick black lines represent the bridges 203, diamond shapes represent both the first touch electrodes 201 (namely the plurality of first touch sub-electrodes 2011) and the second touch electrodes 202 (namely the plurality of second touch sub-electrodes 2021), here, the diamond shapes through which the vertical thick black lines pass represent the first touch electrodes 201 (namely the plurality of first touch sub-electrodes 2011), and the diamond shapes through which the horizontal thick black lines pass represent the second touch electrodes 202 (namely the plurality of second touch sub-electrodes 2021). Meanwhile, in FIG. 5 which is to be described hereinafter, vertical thick black lines represent the black matrix 301, vertical thick white lines represent the first touch electrodes 201, and horizontal thick gray lines represent the second touch electrodes 202. Correspondingly, in FIG. 11 and FIG. 12 which are to be described hereinafter and which relates to a method of manufacturing a touch display substrate, directly connected diamond shapes in a vertical direction represent the first touch electrodes 201 (namely a plurality of directly connected first touch sub-electrodes 2011), separately arranged diamond shapes in a horizontal direction represent the second touch electrodes 202 (namely a plurality of separately arranged second touch sub-electrodes 2021); in FIG. 12, thick black lines represent the black matrix 301, small white rectangles in the horizontal thick black lines represent the bridge holes 303. In the above figures, the plurality of first touch sub-electrodes 2011 are directly connected, and the plurality of second touch sub-electrodes 2021 are separately arranged.

In a first exemplary structure of the touch layer 20, as shown in FIG. 4, the first touch electrodes 201 and the second touch electrodes 202 are in a same layer, each of the first touch electrodes 201 includes a plurality of directly connected first touch sub-electrodes 2011, and each of the second touch electrodes 202 includes a plurality of separately arranged second touch sub-electrodes 2021. The touch layer 20 further includes: bridges 203 provided on the black matrix 301 respectively at the intersections of the first touch electrodes 201 and the second touch electrodes 202 and configured to connect adjacent ones of the second touch sub-electrodes 2021.

In addition, the specific material of the bridges 203 is not limited, as long as it is a conductive material that is capable of connecting the adjacent second touch sub-electrodes 2021. Since the first touch electrode 201 and the second touch electrode 202 are insulated from each other at the intersections of the first touch electrode 201 and the second touch electrode 202 by the black matrix 301, and the bridge 203 is used to connect the adjacent ones of the second touch sub-electrodes 2021, the black matrix 301 is necessarily provided between the bridge 203 and the first touch electrode 201, and an orthographic projection of the bridge 203 on the base substrate 60 and an orthographic projection of the black matrix 301 on the base substrate 60 have an overlapping region. Based on this, since the material of the black matrix 301 is a light shielding material, the material of the bridge 203 may be a transparent conductive material or a non-transparent conductive material. When the material of the bridge 203 is a transparent conductive material, the material of the bridge 203 may be the same as or different from the materials of the first touch electrode 201 and the second touch electrode 202, which is not limited thereto. As shown in FIG. 2(a), FIG. 2(b) and FIG. 2(c), in case that the bridge 203 passes through the bridge hole (which will be described later in the description of FIG. 12) in the black matrix 301 and connects to the second touch sub-electrodes 2021, if the bridge 203 is made of a transparent conductive material, the light emitted by the touch display apparatus may pass through the bridge 203 at the position of the bridge hole, thereby causing light leakage and adversely affecting the display effect. Therefore, in these exemplary embodiments of the present disclosure, the material of the bridge 203 is a non-transparent conductive material. For example, the material of the bridge 203 may be, but not limited to, these conductive materials having a relatively large optical density (OD) value such as Mo (molybdenum), Cu (copper), and Cr (chromium).

Based on this, the spacing between adjacent bridges 203 is not limited, and the position of the bridge 203 is set according to the size and position of the first touch electrode 201 and the second touch electrode 202 (i.e., according to the design of the touch layer 20).

Since one color photoresist 302 corresponds in size and in position to one pixel, the spacing of one color photoresist 302 equals to the spacing of one pixel. For example, as shown in FIG. 2(a) and FIG. 2(b), the adjacent bridges 203 are spaced apart by one pixel, or else, as shown in FIG. 2(c), the adjacent bridges 203 are spaced apart by two or more pixels (the adjacent bridges 203 are spaced apart by two pixels, as illustrated in an example of FIG. 2(c)). The spacing between adjacent bridges 203 can be, but is not limited to, one or more pixel, namely one or more color photoresist 302. Since the problem of inconsistent local optical brightness may be caused when the adjacent bridges 203 are not spaced apart by one or more pixel as whole, in the exemplary embodiments of the present disclosure, the adjacent bridges 203 are spaced apart by one or more pixel, namely by one or more color photoresist 302, so that there is no problem with local optical brightness inconsistency.

It should be noted that when the touch layer 20 is manufactured, as shown in FIG. 2(a), the first touch electrodes 201 and the second touch electrodes 202 may be first formed, then the black matrix 301 is formed, and finally the bridges 203 are formed; or else, as shown in FIG. 2(b), the bridges 203 may be first formed, then the black matrix 301 is formed, and the first touch electrodes 201 and the second touch electrodes 202 are finally formed.

According to the embodiments of the present disclosure, since the first touch electrodes 201 and the second touch electrodes 202 are in the same layer, the first touch electrodes 201 and the second touch electrodes 202 can be simultaneously formed by one patterning process, which simplifies the process of manufacturing the touch display substrate.

In a second exemplary structure of the touch layer 20, as shown in FIG. 3 and FIG. 5, the first touch electrodes 201 and the second touch electrodes 202 are in different layers.

Here, the spacing between the first touch electrodes 201, the size of the first touch electrode 201, the spacing between the second touch electrodes 202, and the size of the second touch electrode 202 are not limited, and may be set according to the needs of the touch operation, as long as it is ensured that an orthographic projection of the black matrix 301 on the base substrate 60 at least covers an overlapping region of an orthographic projection of the first touch electrode 201 on the base substrate 60 and an orthographic projection of the second touch electrode 202 on the base substrate 60, as a result, the first touch electrode 201 and the second touch electrode 202 can be insulated from each other by the black matrix 301.

In some embodiments, the first touch electrodes 201 can be first formed, then the black matrix 301 is formed, and finally the second touch electrodes 202 are formed, as shown in FIG. 5; or else, the second touch electrodes 202 can be first formed, then the black matrix 301 is formed, and finally the first touch electrodes 201 are formed.

According to the embodiments of the present disclosure, in the present exemplary structure, since each first touch electrode 201 and each second touch electrode 202 are completely continuous strip electrodes without disconnection, no bridge 203 is required to be provided for the first touch electrode 201 and the second touch electrode 202, thereby reducing difficulty of manufacturing the first touch electrode 201 and the second touch electrode 202.

Fifthly, in addition to the color photoresists 302, the black matrix 301 and the touch layer 20, the base substrate 60 may be provided with other film layers required for the touch display substrate as needed, which is not limited thereto.

On the basis of this, when the touch display substrate according to the embodiments of the present disclosure is applied to a flexible touch display apparatus, the bending radius of the flexible touch display apparatus is reduced as the thickness of the touch display substrate is reduced, thereby avoiding the problem that the film layer is easily broken at the bending point, and improving the degree of bending or folding of the flexible touch display apparatus. Further, when the touch display substrate according to the embodiments of the present disclosure is applied to a touch display apparatus, the thickness of the touch display apparatus is reduced as the thickness of the touch display substrate is reduced, so that a light-emitting area of the touch display apparatus is increased, thereby increasing a viewing angle of the touch display apparatus.

Based on the above, the base substrate 60 according to the embodiments of the present disclosure may be a rigid base substrate or a flexible base substrate. When the base substrate 60 is a flexible base substrate, the touch display substrate is a flexible touch display substrate, which can realize the bending function. The material of the flexible base substrate may be an organic material.

In some embodiments, as shown in FIG. 6, the touch display substrate further includes a planarization layer 70 (, e.g., an over coat, OC for short) provided at a side of the touch layer 20, the color photoresists 302, and the black matrix 301 away from the base substrate 60. That is, the planarization layer 70 and the base substrate 60 are disposed on the opposite sides of the touch layer 20, the color photoresists 302, and the black matrix 301, respectively, to sandwich the touch layer 20, the color photoresists 302, and the black matrix 301 therebetween.

The material of the planarization layer 70 is not limited, as long as a flattening function can be achieved. The material of the planarization layer 70 may be an organic material or an inorganic material.

In the embodiments of the present disclosure, provision of the planarization layer 70 on the touch layer 20, the color photoresists 302 and the black matrix 301 can flat the surface of the touch display substrate. According to the embodiments of the present disclosure, there is provided a touch display apparatus including the touch display substrate according to any one of the abovementioned embodiments.

In some embodiments, the touch display apparatus may be a liquid crystal display (LCD) apparatus; or an organic light-emitting diode display (OLED) apparatus; of course, it may also be a quantum dot light-emitting display (QLED) apparatus or other types of touch display apparatus.

In some embodiments, the touch display apparatus can be any apparatus that displays an image of whether moving (e.g., video) or still (e.g., a still picture), regardless of text or picture. More specifically, it is contemplated that the touch display apparatus according to the embodiments of the present disclosure may be implemented in or associated with a plurality of electronic devices such as, but not limited to, Mobile Phone, Wireless Device, Personal Data Assistant (PDA), Handheld or Portable Computer, GPS Receiver/Navigator, Camera, MP4 Video Player, Camera, Game Console, Watch, Clock, Calculator, TV Monitor, Flat Panel Display, Computer Monitor, Automotive displays (e.g., odometer displays, etc.), Navigator, Cockpit Control and/or Display, Camera View Displays (e.g., rear view camera displays in vehicles), Electronic Photographs, Electronic Billboards or Signs, Projector, Displays of architectural structures, packaging and aesthetic structures (for example, image of a piece of jewelry), etc.. In addition, the touch display apparatus according to the embodiment of the present disclosure may also be a touch display panel.

According to the embodiments of the present disclosure, there is provided a touch display apparatus including the touch display substrate according to any one of the abovementioned embodiments. The touch display substrate in the touch display apparatus has the same or corresponding structures and advantageous effects as the touch display substrate according to the abovementioned embodiments. Since the structures and advantageous effects of the touch display substrate have been described in the abovementioned embodiments in detail, they are not repeated herein for the sake of brevity.

In case that the touch display apparatus is an OLED touch display apparatus or a QLED touch display apparatus, referring to FIG. 7 and FIG. 8, the touch display substrate further includes a display layer 80 and a packaging layer 90 provided at a side of the touch layer 20, the color photoresists 302 and the black matrix 301 close to the base substrate 60, and the display layer 80 is between the base substrate 60 and the packaging layer 90. The display layer 80 includes a plurality of sub-pixels, each of which includes a first electrode 801, an light-emitting function layer 802 and a second electrode 803.

It should be noted that the packaging layer 90 may be a thin film encapsulation (TFE for short) encapsulated by a thin film; or may be a substrate encapsulation encapsulated by a substrate. When the packaging layer 90 is a thin film encapsulation, as shown in FIG. 8, a buffer layer 100 may be disposed on a side of the packaging layer away from the base substrate 60. The material of the buffer layer 100 may be selected from at least one of SiNₓ (silicon nitride), SiOₓ (silicon oxide), or SiOₓN_{y} (silicon oxynitride).

In some embodiments, the first electrode 801 may be an anode and the second electrode 803 may be a cathode; or else, the first electrode 801 may be a cathode and the second electrode 803 may be an anode. The first electrode 801 and the second electrode 803 are used to drive the light-emitting function layer 802 to emit light.

In some embodiments, the light-emitting function layer 802 may include a light emitting layer, and may further include at least one of an electron injection layer, an electron transport layer, a hole injection layer, and a hole transport layer. Among them, the light emitting layer can emit white light, or else can emit lights of red, green and blue primary colors.

Based on this, the display layer 80 may further include a pixel definition layer (PDL) 804 for spacing adjacent sub-pixels. In addition, the display layer 80 may further include a thin film transistor. The thin film transistor may be an amorphous silicon thin film transistor (a-Si), a low temperature poly-silicon (LTPS) thin film transistor, an organic thin film transistor, or a metal oxide thin film transistor such as IGZO (Indium Gallium Zinc Oxide) thin film transistor, etc..

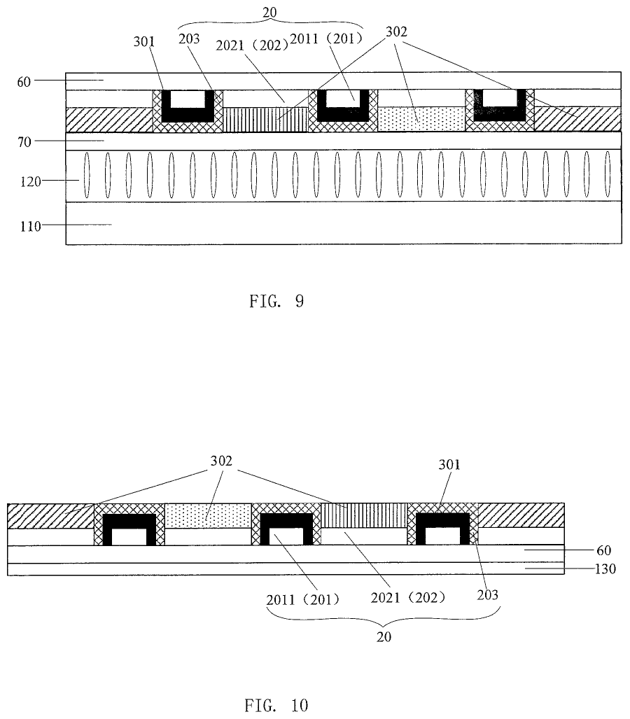

In case that the touch display apparatus is a liquid crystal touch display apparatus, as shown in FIG. 9, the touch display apparatus further includes: an array substrate 110, and a liquid crystal layer 120 provided between the array substrate 110 and the touch display substrate.

In some embodiments, the array substrate 110 includes a thin film transistor. The thin film transistor may be an amorphous silicon thin film transistor, a low temperature polysilicon thin film transistor, an organic thin film transistor, or a metal oxide thin film transistor.

According to the embodiments of the present disclosure, there is further provided a method of manufacturing a touch display substrate, e.g., the touch display substrate according to any one of the abovementioned embodiments. Referring to FIG. 13, the method at least includes the following steps S100 and S101.

In the step S100, on a base substrate 60, a plurality of color photoresists 302 and a black matrix 301 configured to separate the plurality of color photoresists 302 are formed.

The specific material of the black matrix 301 is not limited as long as it is a light-shielding and insulating material. In addition, the color photoresists 302 may be, for example, a red photoresist pattern, a green photoresist pattern, and a blue photoresist pattern, or else, may be a yellow photoresist pattern, a magenta photoresist pattern, and a cyan photoresist pattern.

In the step S101, a touch layer 20 including a plurality of first touch electrodes 201 arranged in a first direction and a plurality of second touch electrodes 202 arranged in a second direction, the second direction being different from the first direction is formed, wherein the first touch electrodes 201 intersect with the second touch electrodes 202, and the first touch electrodes 201 and the second touch electrodes 202 are insulated from each other at intersections of the first touch electrodes 201 and the second touch electrodes 202 by the black matrix 301.

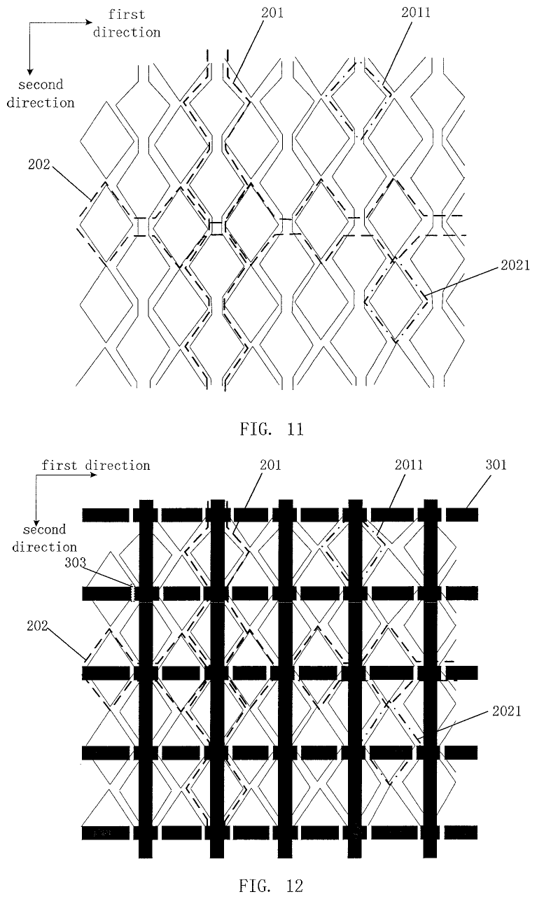

In some embodiments, in case that the base substrate 60 is a flexible base substrate, as shown in FIG. 10, the flexible base substrate may be first attached to a rigid substrate 130 such as a glass substrate, and then film layers such as the touch layer 20, the black matrix 301, the color photoresists 302, etc., may be formed on the flexible base substrate. After the touch display substrate is prepared, the flexible base substrate is stripped from the rigid substrate 130.

It should be noted that the order in which the step S100 and the step S101 appear does not indicate the order of manufacturing, and only indicate the color photoresists 302, the black matrix 301, the first touch electrode 201, and the second touch electrode 202 are formed on the base substrate 60. The following steps S200-S202, S300-S302, and S400-S402 will elaborate the order of manufacturing the film layers on the touch display substrate in details.

According to the embodiments of the present disclosure, there is provided the method of manufacturing the touch display substrate according to any one of the abovementioned embodiments. The method of manufacturing the touch display substrate has the same or corresponding characteristics and advantageous effects as the touch display substrate according to any one of the abovementioned embodiments. Since the characteristics and advantageous effects of the touch display substrate have been described in the abovementioned embodiments in detail, they are not repeated herein for the sake of brevity.

Several exemplary embodiments of the method of manufacturing the touch display substrate are provided as below.

In one exemplary embodiment, as shown in FIG. 2(a) and FIG. 2(c), FIG. 11 and FIG. 14, the method for manufacturing the touch display substrate specifically includes the following steps S200-S202.

In the step S200, referring to FIG. 11, a plurality of first touch electrodes 201 arranged in a first direction and a plurality of second touch electrodes 202 arranged in a second direction are formed on a base substrate 60, the second direction being different from the first direction. The first touch electrodes 201 intersect with the second touch electrodes 202, and each of the first touch electrodes 201 includes a plurality of directly connected first touch sub-electrodes 2011, and each of the second touch electrodes 202 includes a plurality of separately arranged second touch sub-electrodes 2021.

In some embodiments, a transparent conductive film may be first formed on the base substrate 60, and then the transparent conductive film may be patterned to form the first touch sub-electrodes 2011 and the second touch sub-electrodes 2021 simultaneously. The transparent conductive film can be formed by a chemical vapor deposition process or a sputtering process. The patterning process may specifically include a coating of photoresist, a mask, an exposure, a development, and an etching process.

In the step S201, referring to FIG. 12 (in which the color photoresists are not labeled for the sake of clarity), a plurality of color photoresists and a black matrix 301 configured to separate the plurality of color photoresists are formed, and the black matrix 301 at least covers a portion of the first touch electrode 201 at the intersection of the first touch electrode 201 and the second touch electrode 202.

In some embodiments, the color photoresists may be formed first, and then the black matrix 301 is formed; or else, the black matrix 301 may be formed first, and then the color photoresists are formed.

It should be noted that, when manufacturing the black matrix 301, the black matrix 301 should not block a position where the bridge 203 communicates with the second touch sub-electrodes 2021 in the step S202 to be described below. If the black matrix 301 blocks the position where the bridge 203 communicates with the second touch sub-electrodes 2021, as shown in FIG. 12, a bridge hole 303 for the bridge 203 needs to be reserved when manufacturing the black matrix 301.

In some embodiments, the color photoresists and black matrix 301 can be formed by exposure and development processes

In the step S202, referring to FIG. 4, bridges 203 are formed respectively at the intersections of the first touch electrodes 201 and the second touch electrodes 202, and the bridges 203 are configured to connect adjacent ones of the second touch sub-electrodes 2021.

In some embodiments, since the bridge 203 is formed on the black matrix 301, and the material of the black matrix 301 is a light-shielding and insulating material, the material of the bridge 203 may be a transparent conductive material or a non-transparent conductive material. When the bridge 203 is connected to the second touch sub-electrodes 2021 through the bridge holes 303 in the black matrix 301, if the bridge 203 is a transparent conductive material, the light emitted by the touch display apparatus may pass through the bridge 203 at the position of the bridge hole 303, which causes light leakage and adversely affects the display effect. Therefore, in the exemplary embodiments of the present disclosure, the material of the bridge 203 is a non-transparent conductive material. For example, the material of the bridge 203 may be, but not limited to, some conductive materials having a relatively large optical density value such as Mo, Cu, and Cr.

Based on this, the spacing between adjacent bridges 203 is not limited, and the position of the bridge 203 is set according to the size and position of the first touch electrode 201 and the second touch electrode 202. For example, the adjacent bridges 203 may be spaced apart by one pixel, or else, the adjacent bridges may be spaced apart by two or more pixels. The spacing between adjacent bridges 203 can be, but is not limited to, one or more pixel, that is, the adjacent bridges 203 are spaced apart by one or more pixel, namely by one or more color photoresist 302.

In some embodiments, the process of forming the bridge 203 may specifically be to first form a conductive film, and then pattern the conductive film to form the bridge 203.

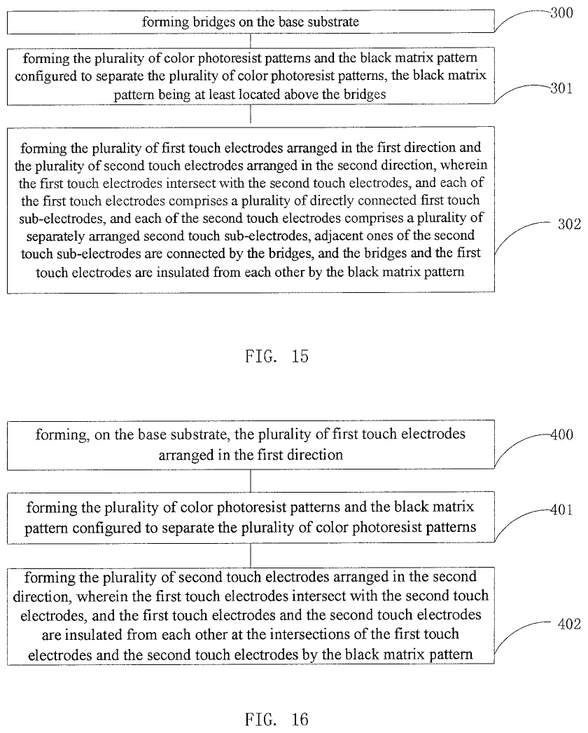

In another exemplary embodiment, as shown in FIG. 2(b) and FIG. 15, the method for manufacturing the touch display substrate specifically includes the following steps S300-S302.

In the step S300, bridges 203 are formed on the base substrate 60.

In some embodiments, when the bridges 203 are formed, the spacing between the adjacent ones of the bridges 203 is not limited, and the positions of the bridges 203 are set according to the size and position of the first touch electrodes 201 and the second touch electrodes 202. For example, the spacing between adjacent ones of the bridges 203 can be, but is not limited to, one or more pixel, that is, the adjacent bridges 203 are spaced apart by one or more pixel, namely by one or more color photoresist 302.

In the step S301, a plurality of color photoresists 302 and a black matrix 301 configured to separate the plurality of color photoresists 302 are formed, the black matrix 301 is at least located above the bridges 203.

In some embodiments, the color photoresists 302 may be formed first, and then the black matrix 301 is formed; or else, the black matrix 301 may be formed first, and then the color photoresists 302 are formed.

It should be noted that, when manufacturing the black matrix 301, the black matrix 301 should not block a position where the bridge 203 communicates with the second touch sub-electrodes 2021 in the step S302 to be described below, that is, the black matrix 301 should not completely cover the bridges 203. A bridge hole 303 for the bridge 203 needs to be reserved when manufacturing the black matrix 301.

In the step S302, a plurality of first touch electrodes 201 arranged in a first direction and a plurality of second touch electrodes 202 arranged in a second direction are formed, the second direction being different from the first direction. The first touch electrodes 201 intersect with the second touch electrodes 202, and each of the first touch electrodes 201 includes a plurality of directly connected first touch sub-electrodes 2011, and each of the second touch electrodes 202 includes a plurality of separately arranged second touch sub-electrodes 2021. Adjacent ones of the second touch sub-electrodes 2021 are connected by a bridge 203, and the bridge 203 and the first touch electrode 201 are insulated from each other by the black matrix 301.

In some embodiments, since the black matrix 301 is provided on the bridges 203, the bridges 203 and the first touch electrodes 201 are insulated from each other, and thus the first touch electrodes 201 and the second touch electrodes 202 can be insulated from each other.

Since the first touch electrodes 201 and the second touch electrodes 202 are simultaneously manufactured in the above steps S200-S202 and S300-S302, the manufacturing process of the touch display substrate is simplified.

In a further exemplary embodiment, as shown in FIG. 3 and FIG. 16, the method for manufacturing the touch display substrate specifically includes the following steps S400-S402.

In the step S400, a plurality of first touch electrodes 201 arranged in a first direction are formed on the base substrate 60.

In the step S401, a plurality of color photoresists 302 and a black matrix 301 configured to separate the plurality of color photoresists 302 are formed.

In some embodiments, the color photoresists 302 may be formed first, and then the black matrix 301 is formed; or else, the black matrix 301 may be formed first, and then the color photoresists 302 are formed.

In the step 5402, a plurality of second touch electrodes 202 arranged in a second direction are formed, the second direction being different from the first direction, wherein the first touch electrodes 201 intersect with the second touch electrodes 202, and the first touch electrodes 201 and the second touch electrodes 202 are insulated from each other at intersections of the first touch electrodes 201 and the second touch electrodes 202 by the black matrix 301.

It should be noted that the spacing between the first touch electrodes 201, the size of the first touch electrode 201, the spacing between the second touch electrodes 202, and the size of the second touch electrode 202 are not limited, and may be set according to the needs of the touch operation. The shape and size of the black matrix 301 can be set according to the needs of the pixel. Based on this, when manufacturing the black matrix 301, the first touch electrodes 201 and the second touch electrode 202, it should also be ensured that an orthographic projection of the black matrix 301 on the base substrate 60 at least covers an overlapping region of an orthographic projection of the first touch electrode 201 on the base substrate 60 and an orthographic projection of the second touch electrode 202 on the base substrate 60, such that the black matrix 301 can insulate the first touch electrode 201 and the second touch electrode 202 from each other.

Based on the above, when manufacturing the touch display apparatus, if the touch display apparatus is an OLED touch display apparatus or a QLED touch display apparatus, before forming the touch layer 20, the color photoresists 302, and the black matrix 301 on the base substrate 60, as shown in FIG. 7, a display layer 80 and a packaging layer 90 may also be sequentially formed on the base substrate 60. The packaging layer 90 can be a thin film encapsulation or a substrate encapsulation. In case that the packaging layer 90 is a thin film encapsulation, as shown in FIG. 8, a buffer layer 100 may also be formed on the packaging layer 90. The manufacturing process of the display layer 80 can refer to the manufacturing process of the related art, and the details are not described herein again. After forming the touch layer 20, the color photoresists 302, and the black matrix 301 on the base substrate 60, as shown in FIG. 7, a planarization layer 70 can also be formed.

In case that the touch display apparatus is a liquid crystal display apparatus, after forming the touch layer 20, the color photoresists 302, and the black matrix 301 on the base substrate 60, as shown in FIG. 9, a planarization layer 70 may also be formed. After manufacturing the touch display substrate, the manufactured touch display substrate and the array substrate 110 are assembled in an assembling process. Here, the assembling process can refer to the assembling process in the related art, including such as the processes of providing an orientation layer on the planarization layer 70 and the array substrate 110, coating edge sealant, liquid crystal dropping, and the like, and the details are not described herein.

In the touch display substrate and the method of manufacturing the same according the embodiments of the present disclosure, the first touch electrode 201 and the second touch electrode 202 in the touch layer 20 are insulated from each other at the intersection of the first touch electrode 201 and the second touch electrode 202 by the black matrix 301, so that no separate insulating layer is required to be provided at the intersection of the first touch electrode 201 and the second touch electrode 202. In addition, since the first touch electrode 201 and the second touch electrode 202 in the touch layer 20 are insulated from each other at the intersection of the first touch electrode 201 and the second touch electrode 202 by the black matrix 301, the black matrix 301 is necessarily formed in the process of manufacturing the touch layer 20, instead of being formed after manufacturing the touch layer 20, or of being formed before manufacturing the touch layer 20, so there is no need to provide an insulating layer between the touch layer 20 and the color filter 30 (which includes color photoresists 302 and the black matrix 301). In this way, compared with the touch display substrate in related art in which a first insulating layer 40 is provided between the touch layer 20 and the color filter 30 and a second insulating layer 50 is provided at the intersection of the first touch electrode 201 and the second touch electrode 202, the touch display substrate according to the embodiment of the present disclosure reduces its thickness by reducing provision of the two insulating layers. In addition, according to the embodiments of the present disclosure, the manufacturing processes of the first insulating layer 40 and the second insulating layer 50, such as a CVD (Chemical Vapor Deposition) process and an etching process of the second insulating layer 50 are eliminated, which improves production efficiency of the touch display substrate and increases the production capacity.

Although some exemplary embodiments of the present disclosure have been shown and described above, it would be appreciated by a person skilled in the art that many modifications or changes may be made therein without departing from the principle and spirit of the present disclosure, the scope of which is defined in the appended claims and their equivalents.

What is claimed is:

1. A touch display substrate comprising:
a base substrate ;
a plurality of color photoresists on the base substrate;
a black matrix configured to separate the plurality of color photoresists; and
a touch layer comprising a plurality of first touch electrodes arranged in a first direction and a plurality of second touch electrodes arranged in a second direction, the second direction being different from the first direction;
wherein the first touch electrodes intersect with the second touch electrodes, and the first touch electrodes and the second touch electrodes are insulated from each other at intersections of the first touch electrodes and the second touch electrodes by the black matrix.

2. The touch display substrate of claim 1, wherein the first touch electrodes and the second touch electrodes are in a same layer, each of the first touch electrodes comprises a plurality of directly connected first touch sub-electrodes, and each of the second touch electrodes comprises a plurality of separately arranged second touch sub-electrodes; and
the touch layer further comprises: bridges provided respectively at the intersections of the first touch electrodes and the second touch electrodes and configured to connect adjacent ones of the second touch sub-electrodes.

3. The touch display substrate of claim 2, wherein adjacent ones of the bridges are spaced apart by one or more of the color photoresists.

4. The touch display substrate of claim 2, wherein the bridge is made of conductive material, and the black matrix is made of non-conductive material.

5. The touch display substrate of claim 1, wherein the first touch electrodes and the second touch electrodes are in different layers, and in a direction perpendicular to the base substrate, the first electrodes, the black matrix, and the second touch electrodes are arranged on the base substrate successively.

6. The touch display substrate of claim 5, wherein both the first touch electrodes and the second touch electrodes are strip-shaped electrodes, and the black matrix is made of non-conductive material.

7. The touch display substrate of claim 1, wherein an orthographic projection of the black matrix on the base substrate at least covers an overlapping region of an orthographic projection of the first touch electrode on the base substrate and an orthographic projection of the second touch electrode on the base substrate.

8. The touch display substrate of claim 1, wherein ones of the first touch electrodes and the second touch electrodes are driving electrodes and the others are touch sensor electrodes.

9. The touch display substrate of claim 1, wherein the base substrate is a flexible base substrate.

10. The touch display substrate of claim 1, wherein the touch display substrate further comprises: a planarization layer provided at a side of the touch layer, the color photoresists and the black matrix away from the base substrate.

11. A touch display apparatus comprising the touch display substrate of claim 1.

12. The touch display apparatus of claim 11, wherein the touch display substrate further comprises: a display layer and a packaging layer provided at a side of the touch layer, the color photoresists and the black matrix close to the base substrate, the display layer being between the base substrate and the packaging layer; and
wherein the display layer comprises a plurality of sub-pixels, each of which comprises a first electrode, a light-emitting function layer and a second electrode.

13. The touch display apparatus of claim 11, further comprising: an array substrate, and a liquid crystal layer between the array substrate and the touch display substrate.

14. A method of manufacturing the touch display substrate of claim 1, the method comprising:
forming, on the base substrate, the plurality of color photoresists and the black matrix configured to separate the plurality of color photoresists; and
forming the touch layer comprising the plurality of first touch electrodes arranged in the first direction and the plurality of second touch electrodes arranged in the second direction, wherein the first touch electrodes intersect with the second touch electrodes, and the first touch electrodes and the second touch electrodes are insulated from each other at the intersections of the first touch electrodes and the second touch electrodes by the black matrix.

15. A method of manufacturing the touch display substrate of claim 1, the method comprising:
forming, on the base substrate, the plurality of first touch electrodes arranged in the first direction and the plurality of second touch electrodes arranged in the second direction, wherein the first touch electrodes intersect with the second touch electrodes, and each of the first touch electrodes comprises a plurality of directly connected first touch sub-electrodes, and each of the second touch electrodes comprises a plurality of separately arranged second touch sub-electrodes;
forming the plurality of color photoresists and the black matrix configured to separate the plurality of color photoresists, the black matrix at least covering a portion of the first touch electrode at the intersection of the first touch electrode and the second touch electrode; and
forming bridges respectively at the intersections of the first touch electrodes and the second touch electrodes, the bridges being configured to connect adjacent ones of the second touch sub-electrodes.

16. The method of claim 15, wherein the step of forming the bridges respectively at the intersections of the first touch electrodes and the second touch electrodes further comprising: forming a conductive film, and patterning the conductive film to form the bridges.

17. A method of manufacturing the touch display substrate of claim 1, the method comprising:
forming bridges on the base substrate;
forming the plurality of color photoresists and the black matrix configured to separate the plurality of color photoresists, the black matrix being at least located above the bridges;
forming the plurality of first touch electrodes arranged in the first direction and the plurality of second touch electrodes arranged in the second direction, wherein the first touch electrodes intersect with the second touch electrodes, and each of the first touch electrodes comprises a plurality of directly connected first touch sub-electrodes, and each of the second touch electrodes comprises a plurality of separately arranged second touch sub-electrodes, adjacent ones of the second touch sub-electrodes are connected by the bridges, and the bridges and the first touch electrodes are insulated from each other by the black matrix.

18. The method of claim 17, wherein the step of forming the bridges further comprising: forming a conductive film, and patterning the conductive film to form the bridges.

19. A method of manufacturing the touch display substrate of claim 1, the method comprising:
forming, on the base substrate, the plurality of first touch electrodes arranged in the first direction;
forming the plurality of color photoresists and the black matrix configured to separate the plurality of color photoresists; and
forming the plurality of second touch electrodes arranged in the second direction, wherein the first touch electrodes intersect with the second touch electrodes, and the first touch electrodes and the second touch electrodes are insulated from each other at the intersections of the first touch electrodes and the second touch electrodes by the black matrix.

20. The method of claim 14, wherein, the black matrix is made of non-conductive material, an orthographic projection of the black matrix on the base substrate at least covers an overlapping region of an orthographic projection of the first touch electrode on the base substrate and an orthographic projection of the second touch electrode on the base substrate, and ones of the first touch electrodes and the second touch electrodes are driving electrodes and the others are touch sensor electrodes.
